(19) United States
(12) Patent Application Publication
(10) Pub. No.: US 2013/0127480 A1
(43) Pub. Date: May 23, 2013

(54) SINGLE SUBSTRATE CAPACITIVE TOUCH SENSOR WITH INTEGRATED DIELECTRIC AND GROUND SHIELD LAYER

(71) Applicants: James M. Cuseo, Los Altos, CA (US); Shin John Choi, Sunnyvale, CA (US)

(72) Inventors: James M. Cuseo, Los Altos, CA (US); Shin John Choi, Sunnyvale, CA (US)

(21) Appl. No.: 13/402,836

(22) Filed: Feb. 22, 2012

Related U.S. Application Data
(60) Provisional application No. 61/561,745, filed on Nov. 18, 2011.

(51) Int. Cl. G01R 27/26; H05K 3/00; B32B 38/14; B32B 37/14; B32B 38/04

(52) U.S. Cl. 324/686; 156/60; 156/247; 156/277; 216/18

(57) ABSTRACT

A compact touch sensor and a touch sensor stack are disclosed. The touch sensor can include a touch sensor circuit integrated with a ground layer on a single substrate. The touch sensor circuit can include two sets of conductive traces separated by a first insulation layer. A second insulation layer can be deposited over the top set of conductive traces of the touch sensor circuit. One or more vias can be included within the first insulation layer to route one or more conductive traces through the first insulation layer. One or more vias can also be included within the substrate to couple one or more conductive traces to the grounding layer. The touch sensor can be laminated to a cover material to form the touch sensor stack. Processes for making the touch sensor and touch sensor stack are also disclosed.

### CROSS-REFERENCE TO RELATED APPLICATIONS

This application claims the benefit, under 35 U.S.C. §119(e), of U.S. Provisional Patent Application No. 61/561,745, filed Nov. 18, 2011, and entitled “Single Substrate Capacitive Touch Sensor with Integrated Dielectric and Ground Shield Layer,” the contents of which are incorporated by reference herein in their entirety for all purposes.

### FIELD

This relates generally to touch sensitive devices and, more specifically, to touch sensors and touch sensor stacks for touch sensitive devices.

### BACKGROUND

Touch sensitive devices, such as trackpads, touch sensitive displays, and the like, have become popular as input devices to computing systems due to their ease and versatility of operation as well as their declining price. The touch sensitive device can allow a user to perform various functions by touching a touch sensor panel using a finger, stylus, or other object. In general, the touch sensitive device can recognize a touch event and the position of the touch event on the touch sensor panel, and the computing system can then interpret the touch event and thereafter can perform one or more actions based on the touch event.

To form the touch sensor panels used in these touch sensitive devices, a touch circuit can be formed on a thin substrate material to form a printed circuit board (PCB). This PCB can then be laminated to a cover material and a dielectric material having a shielding layer. While this modular design provides flexibility in the components used to form the panel, the design creates an increased risk of panel failure (e.g., due to separation between components) and an increased panel thickness.

### SUMMARY

A compact touch sensor and a touch sensor stack are disclosed. The touch sensor can include a touch sensor circuit integrated with a ground layer on a single substrate. The touch sensor circuit can include two sets of conductive traces separated by a first insulation layer. A second insulation layer can be deposited over the top set of conductive traces of the touch sensor circuit. One or more vias can be included within the first insulation layer to route one or more conductive traces through the first insulation layer. One or more vias can also be included within the substrate to couple one or more conductive traces to the grounding layer. The touch sensor can be laminated to a cover material to form the touch sensor stack. The touch sensor and touch sensor stack can advantageously provide a more compact structure for space savings and performance improvement.

Processes for making the touch sensor and touch sensor stack are also disclosed.

### BRIEF DESCRIPTION OF THE DRAWINGS

FIG. 1 illustrates an exemplary touch sensor that can be used with a touch sensitive device according to various embodiments.

FIG. 2 illustrates a cross-sectional view of an exemplary touch sensor according to various embodiments.

FIG. 3 illustrates a cross-sectional view of an exemplary touch sensor stack according to various embodiments.

FIG. 4 illustrates an exemplary process for making a touch sensor according to various embodiments.

FIG. 5 illustrates an exemplary process for making a touch sensor stack according to various embodiments.

FIG. 6 illustrates an exemplary system for making a touch sensor and touch sensor stack according to various embodiments.

FIG. 7 illustrates an exemplary personal device that includes a touch sensor stack according to various embodiments.

FIG. 8 illustrates an exemplary personal device that includes a touch sensor stack according to various embodiments.

FIG. 9 illustrates an exemplary personal device that includes a touch sensor stack according to various embodiments.

### DETAILED DESCRIPTION

In the following description of example embodiments, reference is made to the accompanying drawings in which it is shown by way of illustration specific embodiments that can be practiced. It is to be understood that other embodiments can be used and structural changes can be made without departing from the scope of the various embodiments.

This relates to compact touch sensors and touch sensor stacks. The touch sensor can include a touch sensor circuit integrated with a ground layer on a single substrate. The touch sensor circuit can include two sets of conductive traces separated by a first insulation layer. A second insulation layer can be deposited over the top set of conductive traces of the touch sensor circuit. One or more vias can be included within the first insulation layer to route one or more conductive traces through the first insulation layer. One or more vias can also be included within the substrate to couple one or more conductive traces to the grounding layer. The touch sensor can be laminated to a cover material to form the touch sensor stack. Processes for making the touch sensor and touch sensor stack are also disclosed. Accordingly, the touch sensor and the touch sensor stack can be advantageously thinner, thereby providing a thinner touch sensor panel housing the sensor and sensor stack. Additionally, the touch sensor and the touch sensor stack can cause the touch sensor panel to have a decreased panel failure risk due to a reduction in the number of components used.

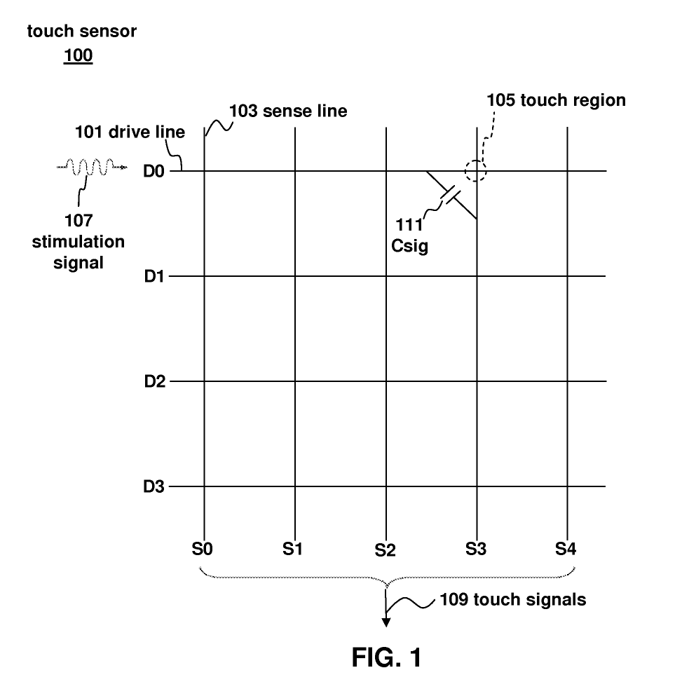

FIG. 1 illustrates touch sensor 100 that can be used to detect touch events on a touch sensitive device, such as a mobile phone, tablet, touchpad, portable computer, portable media player, or the like. Touch sensor 100 can include an array of touch region 105 that can be formed at the crossing points between rows of drive lines 101 (D0-D3) and columns of sense lines 103 (S0-S4). Each touch region 105 can have an associated mutual capacitance Csig 111 formed between the crossing drive lines 101 and sense lines 103 when the drive lines are stimulated. The drive lines 101 can be stimulated by stimulation signals 107 provided by drive circuitry (not shown) and can include an alternating current (AC) waveform. The sense lines 103 can transmit touch signals 109 indicative of a touch at the touch sensor 100 to sense circuitry (not shown), which can include a sense amplifier for each sense line.

To sense a touch at the touch sensor 100, drive lines 101 can be stimulated by the stimulation signals 107 to capacitively couple with the crossing sense lines 103, thereby forming a capacitive path for coupling charge from the drive lines 101 to the sense lines 103. The crossing sense lines 103 can output touch signals 109, representing the coupled charge or current. When a user's finger (or other object) touches the touch sensor 100, the finger can cause the capacitance Csig 111 to reduce by an amount ΔCsig at the touch location. This capacitance change ΔCsig can be caused by charge or current from the stimulated drive line 101 being shunted through the touching finger to ground rather than being coupled to the crossing sense line 103 at the touch location. The touch signals 109 representative of the capacitance change ΔCsig can be transmitted by the sense lines 103 to the sense circuitry for processing. The touch signals 109 can indicate the touch region where the touch occurred and the amount of touch that occurred at that touch region location.

While the embodiment shown in FIG. 1 includes four drive lines 101 and five sense lines 103, it should be appreciated that touch sensor 100 can include any number of drive lines 101 and any number of sense lines 103 to form the desired number and pattern of touch regions 105. Additionally, while the drive lines 101 and sense lines 103 are shown in FIG. 1 in a crossing configuration, it should be appreciated that other configurations are also possible to form the desired touch region pattern. While FIG. 1 illustrates mutual capacitance touch sensing, other touch sensing technologies may also be used in conjunction with embodiments of the disclosure, such as self-capacitance touch sensing, resistive touch sensing, projection scan touch sensing, and the like. Furthermore, while various embodiments describe a sensed touch, it should be appreciated that the touch sensor 100 can also sense a hovering object and generate hover signals therefrom.

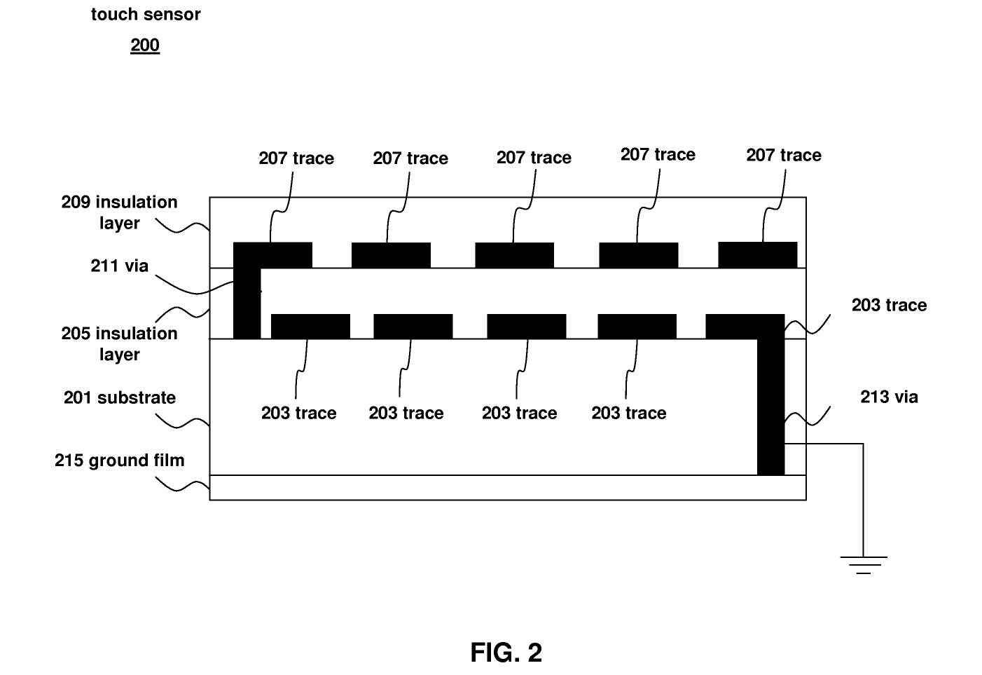

FIG. 2 illustrates a cross-sectional view of an exemplary touch sensor 200 according to various embodiments. Touch sensor 200 can be similar or identical to touch sensor 100. Touch sensor 200 can include substrate 201. In some embodiments, substrate 201 can be formed from polyethylene terephthalate (PET). However, it should be appreciated that other appropriate substrate materials can be used.

Touch sensor 200 can further include traces 203 formed on a surface of substrate 201. Traces 203 can be formed from a conductive material, such as silver, copper, indium tin oxide, other metal oxides, or the like. In some embodiments, traces 203 can be made from a conductive silver ink and can be printed onto the surface of substrate 201. In some embodiments, traces 203 can be used as drive lines 101 of touch sensor 100 and can be deposited onto substrate 201 in parallel, or at least substantially parallel, rows. In other embodiments, traces 203 can be used as sense lines 103 and can be deposited onto substrate 201 in parallel, or at least substantially parallel, rows. In yet other embodiments, traces 203 can be deposited onto substrate 201 to form any desired configuration.

Touch sensor 200 can further include insulation layer 205 covering traces 203. In some embodiments, insulation layer 205 can be formed from a non-conductive material, such as an acrylic material. However, it should be appreciated that any other appropriate non-conductive material can be used.

Touch sensor 200 can further include a second set of traces 207 formed on the surface of insulation layer 205. Like traces 203, traces 207 can be formed from a conductive material, such as silver, copper, indium tin oxide, other metal oxides, or the like. In some embodiments, traces 207 can be made from a conductive silver ink and can be printed onto the surface of insulation layer 205. In some embodiments, traces 207 can be used as sense lines 103 of touch sensor 100 and can be deposited onto insulation layer 205 in parallel, or at least substantially parallel, rows. In other embodiments, traces 207 can be used as drive lines 101 and can be deposited onto insulation layer 205 in parallel, or at least substantially parallel, rows. In yet other embodiments, traces 207 can be deposited onto insulation layer 205 to form any desired configuration. In some embodiments, traces 203 and 207 can be arranged in a crossing configuration, as shown in FIG. 1. Thus, while FIG. 2 shows traces 203 and 207 arranged in the same direction, it should be appreciated that the configuration of the traces is not limited thereto. Specifically, in some embodiments, traces 203 can extend into and out of the page while traces 207 can extend from left to right, or vice versa. Additionally, it should be appreciated that other configurations are also possible to form a desired touch region pattern. It should be further appreciated that, while traces 203 and 207 are at separate levels in FIG. 2, the traces can be on the same level side-by-side with insulation material therebetween to provide the appropriate electrical insulation between adjacent traces.

Touch sensor 200 can further include one or more vias 211 for routing one or more traces 207 through insulation layer 205. In the example shown in FIG. 2, vias 211 route traces 207 down through insulation layer 205 to the same level as traces 203. From there, traces 207 can be coupled to drive or sense circuitry. Vias 211 can be made from the same or a different material as traces 203 and 207. In some embodiments, vias 211 can be formed from a conductive silver ink.

Touch sensor 200 can further include insulation layer 209 covering traces 207 Like insulation layer 205, insulation layer 209 can be formed from a non-conductive material, such as an acrylic. However, it should be appreciated that any other appropriate non-conductive material can be used.

Touch sensor 200 can further include one or more vias 213 for routing traces 203 through substrate 201. In the example shown in FIG. 2, vias 213 route traces 203 down through substrate 201 to couple with ground layer 215. Vias 213 can be made from the same or a different material as traces 203 and 207. In some embodiments, vias 213 can be formed from a conductive silver ink.

Touch sensor 200 can further include ground layer 215 deposited onto a surface of substrate 201 opposite traces 203 and 207. Ground layer 215 can be used to provide touch sensor 200 with a ground reference and provide shielding to traces 203 and 207 from external electrical signals. Ground layer 215 and/or the trace(s) 203 coupled to ground layer 215 can be coupled to ground (e.g., system ground of the device that touch sensor 200 is incorporated into). In some embodiments, ground layer 215 can be formed from aluminum or aluminized mylar. However, it should be appreciated that other appropriate conductive materials can be used to form ground layer 215.

In some embodiments, the thickness of insulation layer 205 can be selected to provide electrical insulation between traces 203 and 207, while still allowing capacitive coupling between traces 203 and 207. The thickness of insulation layer 209 can be selected to provide electrical insulation between traces 207 and an object that can be placed adjacent to insulation layer 209 (e.g., an adhesive and a cover material). Additionally, substrate 201 can have a thickness selected to provide a desired dielectric between the touch circuit (e.g., traces 203 and 207) and ground layer 215.

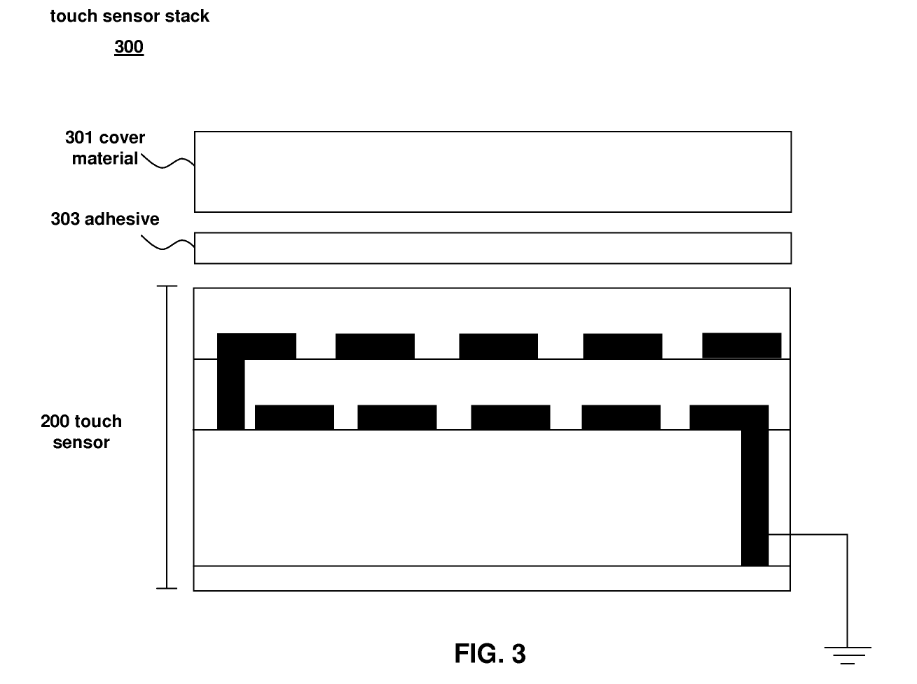

FIG. 3 illustrates a cross-sectional view of an exemplary touch sensor stack 300 according to various embodiments. Touch sensor stack 300 can include a touch sensor, such as touch sensor 200. Touch sensor stack 300 can further include a cover material 301 (e.g., glass, plastic, or the like) laminated to insulation layer 209 of touch sensor 200 by adhesive 303. Adhesive 303 can be a pressure sensitive adhesive (PSA), liquid adhesive, or other appropriate adhesive.

Since touch sensor 200 includes a touch circuit (e.g., traces 203 and 207) integrated with substrate 201 and ground layer 215, touch sensor stack 300 can exclude an additional substrate dielectric layer. As a result, touch sensor stack 300 can be thinner (e.g., less than 165 μm) than typical sensor stacks that can have separate substrates for the touch circuit and the ground layer and can have an overall thickness of 200 μm or more.

In some embodiments, touch sensor stack 300 can be used in a trackpad. In these embodiments, the materials of touch sensor 200, adhesive 303, and cover material 301 can be opaque or transparent, since it is not necessary for a user to be able to see through these materials. In other embodiments, touch sensor stack 300 can be used in a touch-sensitive display. In these embodiments, the materials of touch sensor 200, adhesive 303, and cover material 301 can be transparent to allow a user to see through the touch sensor stack 300 to a display located behind the stack.

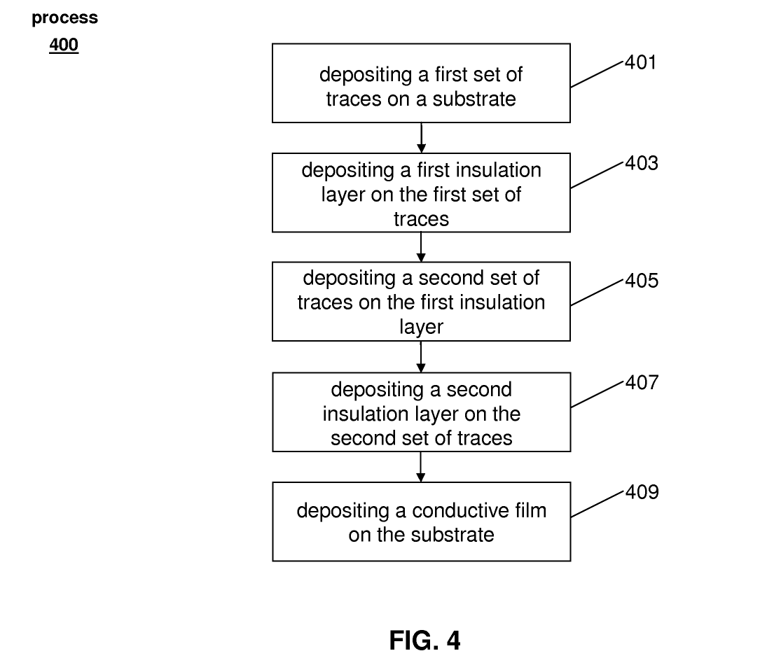

FIG. 4 illustrates an exemplary process for making a touch sensor, such as touch sensors 100 and 200, described above. At block 401, a first set of traces can be deposited on a substrate. For example, traces similar or identical to traces 203 can be deposited on a substrate similar or identical to substrate 201. In some embodiments, a conductive silver ink can be printed onto the surface of the substrate in a desired configuration to form the first set of traces. In other embodiments, other conductive materials can be deposited onto the substrate using known deposition techniques, such as sputtering, laminating, and the like, to form the first set of traces.

In some embodiments, layers of conductive material can be deposited and vertically stacked to form vias similar or identical to vias 211 for routing traces 207 to couple to drive or sense circuitry. The conductive material can be the same conductive silver ink used to form the first set of traces or can be any other appropriate conductive material. In other embodiments, vias can be formed after deposition of the first insulation layer at block 403, as described below.

At block 403, a first insulation layer can be deposited to at least partially cover the first set of traces deposited at block 401. For example, an insulation layer similar or identical to insulation layer 205 can be deposited on a substrate similar or identical to substrate 201 and traces similar or identical to traces 203. In some embodiments, an acrylic insulation layer can be deposited using known deposition techniques. The thickness of the first insulation layer can vary depending on the particular application. One of ordinary skill in the art can determine a desired thickness to provide electrical insulation between the first set of traces and the second set of traces (deposited at block 405).

In some embodiments, where additional layers of conductive material were deposited at block 401 to form vias similar or identical to vias 211, the first insulation layer can be deposited around the additional layers of conductive material, thereby creating vias through the first insulation layer. In other embodiments, where additional layers of conductive material were not deposited at block 401, portions of the first insulation layer can be etched using known etching techniques to form holes in the first insulation layer. These holes can be filled with a conductive material to form vias similar or identical to vias 211.

At block 405, a second set of traces can be deposited on the first insulation layer deposited at block 403. For example, traces similar or identical to traces 207 can be deposited on a first insulation layer similar or identical to insulation layer 205. In some embodiments, a conductive silver ink can be printed onto the surface of the first insulation layer in a desired configuration to form the second set of traces. For example, the second set of traces can form a crossing configuration with the first set of traces similar to drive lines 101 and sense lines 103 shown in FIG. 1. In other embodiments, other conductive materials can be deposited onto the first insulation layer using known deposition techniques, such as sputtering, laminating, and the like, to form the second set of traces.

At block 407, a second insulation layer can be deposited to at least partially cover the second set of traces deposited at block 405. For example, an insulation layer similar or identical to insulation layer 209 can be deposited onto an insulation layer similar or identical to insulation layer 205 and traces similar or identical to traces 207. In some embodiments, an acrylic insulation layer can be deposited using known deposition techniques. The thickness of the second insulation layer can vary depending on the particular application. One of ordinary skill in the art can determine a desired thickness to provide electrical insulation between the second set of traces (deposited at block 405) and an object that can be placed adjacent to the second insulation layer (e.g., an adhesive and a cover material).

At block 409, a conductive layer can be deposited on a surface of the substrate. For example, a conductive layer similar or identical to grounding layer 215 can be deposited on a surface of a substrate similar or identical to substrate 101. The conductive layer can be deposited on a surface of the substrate opposite the first and second set of traces and the first and second insulation layers. In some embodiments, the conductive layer can be an aluminum layer (e.g., aluminized mylar) deposited using any known deposition technique. However, other layers can be deposited using known deposition techniques.

In some embodiments, a portion of the substrate can be etched using known etching techniques to form holes in the substrate. These holes can be filled with a conductive material to form via(s) similar or identical to via(s) 213 for coupling one or more of traces 203 to grounding layer 215. The conductive material can be the same conductive silver ink used to form the first and second set of traces or can be any other appropriate conductive material. The etching of the substrate can be done prior to deposition of the conductive layer at block 409 or prior to deposition of the first set of traces at block 401.

While the blocks of process 400 are shown in a particular order, it should be appreciated that the blocks can be performed in any other order. For example, in some embodiments, the conductive layer can be deposited onto the substrate prior to depositing the first and second traces and the first and second insulation layers. Additionally, in some embodiments, the substrate can be etched and the vias formed in the substrate prior to deposition of the conductive layer, the first and second traces, and the first and second insulation layers. In other embodiments, the substrate can be etched and the vias formed in the substrate after the conductive layer is deposited but before the first set of traces are deposited, or after any of the first and second traces and the first and second insulation layers are deposited but before the conductive layer is deposited.

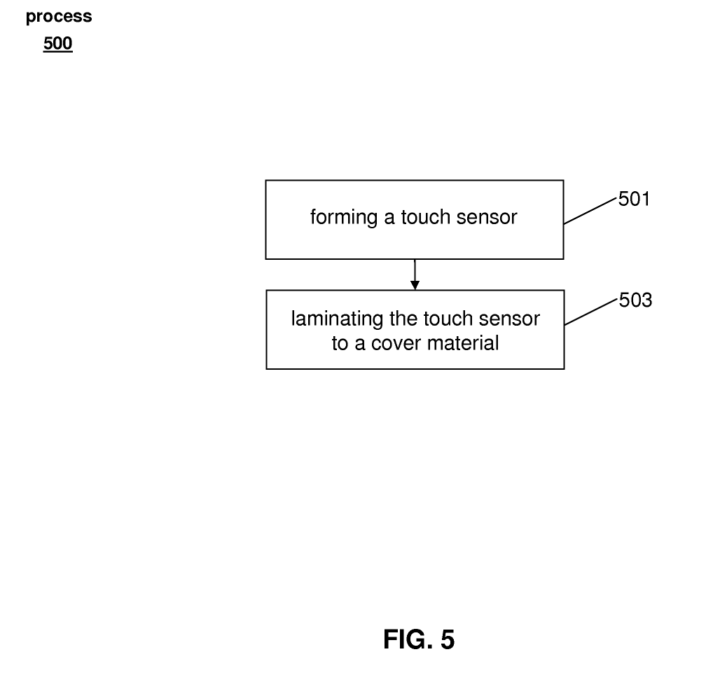

FIG. 5 illustrates an exemplary process for making a touch sensor stack, such as touch sensor stack 300, described above. At block 501, a touch sensor can be formed. The touch sensor can be similar or identical to touch sensors 100 and 200. In some embodiments, the touch sensor can be formed using process 400, described above.

At block 503, the touch sensor can be laminated to a cover material. In some embodiments, a cover material (e.g., plastic, glass, or the like) can be laminated to the touch sensor using a pressure sensitive adhesive. For example, a cover material similar or identical to cover material 301 can be laminated to a touch sensor similar or identical to touch sensor 100 or 200 using an adhesive similar or identical to adhesive 303. In some embodiments, the adhesive can be applied between the insulation layer (e.g., insulation layer 209) of the touch sensor and the cover material.

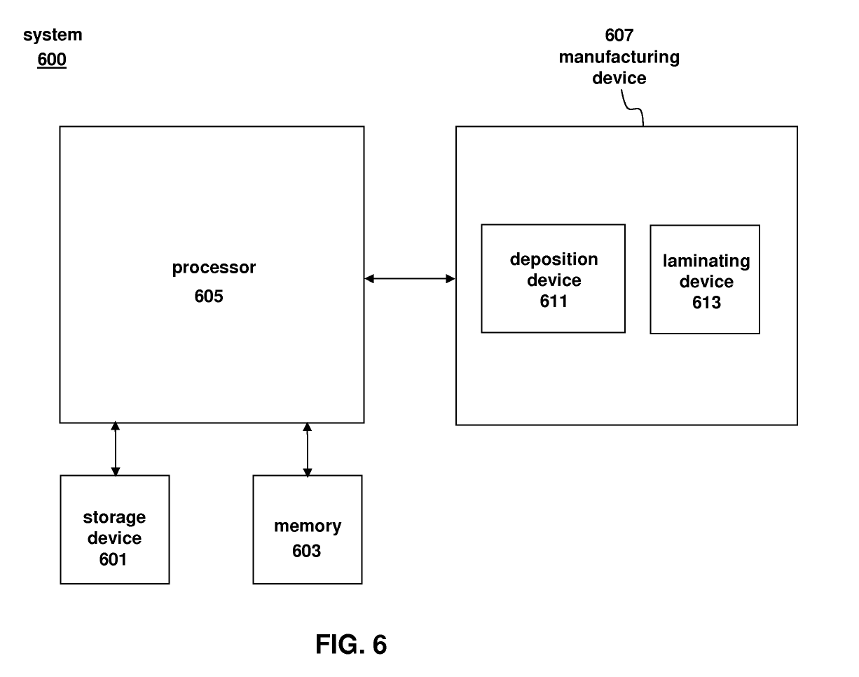

One or more of the functions relating to the manufacturing of a touch sensor or touch sensor stack can be performed by a system similar or identical to system 600 shown in FIG. 6. System 600 can include instructions stored in a non-transitory computer readable storage medium, such as memory 603 or storage device 601, and executed by processor 605. The instructions can also be stored and/or transported within any non-transitory computer readable storage medium for use by or in connection with an instruction execution system, apparatus, or device, such as a computer-based system, processor-containing system, or other system that can fetch the instructions from the instruction execution system, apparatus, or device and execute the instructions. In the context of this document, a “non-transitory computer readable storage medium” can be any medium that can contain or store the program for use by or in connection with the instruction execution system, apparatus, or device. The non-transitory computer readable storage medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The instructions can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport medium can include, but is not limited to, an electronic, magnetic, optical, electromagnetic or infrared wired or wireless propagation medium.

System 600 can further include manufacturing device 607 coupled to processor 605. Manufacturing device 607 can include deposition device 611 configured to deposit the various layers (e.g., traces 203 and 207, insulation layers 205 and 209, vias 211 and 213, and ground layer 215) of the touch sensor onto the substrate, and laminating device 613 configured to laminate the touch sensor (e.g., touch sensor 100 and 200) to a cover material (e.g., cover material 301). Processor 605 can control manufacturing device 607 and its components to deposit the traces having a desired pattern, deposit the insulation layers having desired thicknesses, deposit the vias having desired thicknesses, deposit the conductive layer having a desired thickness, and laminate the touch sensor to the cover material using the appropriate amount of adhesive in a manner similar or identical to that described above with respect to process 600.

It is to be understood that the system is not limited to the components and configuration of FIG. 6, but can include other or additional components in multiple configurations according to various embodiments. Additionally, the components of system 600 can be included within a single device, or can be distributed between two manufacturing device 607, in some embodiments, processor 605 can be located within manufacturing device 607.

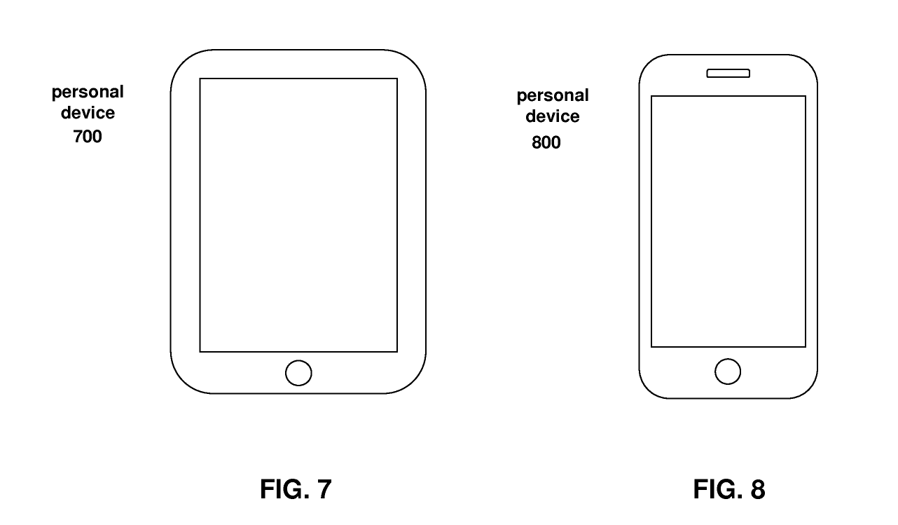

FIG. 7 illustrates an exemplary personal device 700, such as a tablet, that can include a touch sensor and touch sensor stack according to various embodiments.

FIG. 8 illustrates another exemplary personal device 800, such as a mobile phone, that can include a touch sensor and touch sensor stack according to various embodiments.

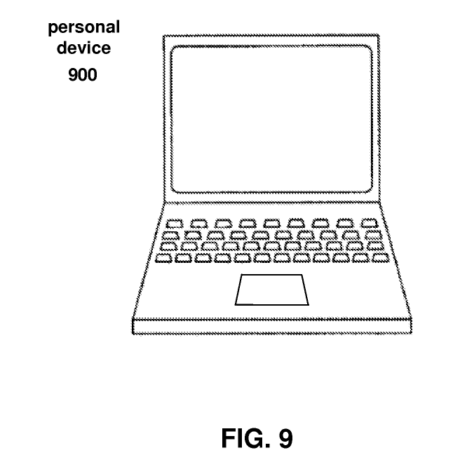

FIG. 9 illustrates another exemplary personal device 900, such as a laptop computer, that can include a touch sensor and touch sensor stack according to various embodiments.

Although embodiments have been fully described with reference to the accompanying drawings, it is to be noted that various changes and modifications will become apparent to those skilled in the art. Such changes and modifications are to be understood as being included within the scope of the various embodiments as defined by the appended claims.

What is claimed is:

1. A touch sensor comprising:
a substrate;
a conductive layer disposed on a first surface of the substrate;
a first plurality of conductive traces disposed on a second surface of the substrate, the second surface opposite the first surface;
a first insulation layer at least partially covering the first plurality of conductive traces;
a second plurality of conductive traces disposed on the first insulation layer; and
a second insulation layer at least partially covering the second plurality of conductive traces.

2. The touch sensor of claim 1, wherein the first insulation layer and second insulation layer comprise an acrylic material.

3. The touch sensor of claim 1 further comprising a via disposed within the substrate, wherein the via couples a conductive trace of the first plurality of traces to the conductive layer.

4. The touch sensor of claim 1 further comprising a via disposed within the first insulation layer, wherein the via is coupled to a conductive trace of the second plurality of traces.

5. A touch sensor comprising:
a substrate;
a conductive layer disposed on a first surface of the substrate; and
a touch sensor circuit disposed on a second surface of the substrate, the touch sensor circuit comprising a plurality of conductive traces, wherein at least one conductive trace is coupled to the conductive layer by a via through the substrate.

6. The touch sensor of claim 5, wherein the conductive layer comprises aluminized mylar.

7. The touch sensor of claim 5, wherein the substrate comprises polyethylene terephthalate.

8. A touch-sensor stack comprising:
a cover material;
a touch sensor comprising:
a substrate;
a conductive layer disposed on a first surface of the substrate;
a touch sensor circuit disposed on a second surface of the substrate, the second surface opposite the first surface; and
an insulation layer covering at least a portion of the touch sensor circuit; and
an adhesive layer coupling the cover material to the insulation layer of the touch sensor.

9. The touch-sensor stack of claim 8, wherein the touch-sensor stack is incorporated within a device, and wherein the conductive layer is coupled to a system ground of the device, the conductive layer configured to ground the touch sensor and to shield the touch sensor circuit from electrical interference.

10. The touch-sensor stack of claim 8, wherein the adhesive layer comprises a pressure-sensitive adhesive.

11. A touch-sensitive device comprising:
a cover material;
a touch sensor comprising:
a substrate;
a conductive layer disposed on a first surface of the substrate;
a first plurality of conductive traces disposed on a second surface of the substrate, the second surface opposite the first surface;
a first insulation layer at least partially covering the first plurality of conductive traces;
a second plurality of conductive traces disposed on the first insulation layer; and
a second insulation layer at least partially covering the second plurality of conductive traces; and
an adhesive layer coupling the cover material to the second insulation layer of the touch sensor.

12. The touch-sensitive device of claim 11, wherein the cover material comprises glass or plastic.

13. The touch-sensitive device of claim 11, wherein the first plurality of conductive traces is coupled to drive circuitry configured to stimulate the first plurality of conductive traces with a stimulation signal.

14. The touch-sensitive device of claim 13, wherein the second plurality of conductive traces are configured to transmit a touch signal in response to the stimulation signal.

15. The touch-sensitive device of claim 14, wherein the second plurality of conductive traces is coupled to a sense circuit configured to receive the touch signal.

16. A method for manufacturing a touch-sensitive device, the method comprising:
forming a touch sensor, wherein forming the touch sensor comprises:
depositing a conductive layer on a first surface of a substrate;
depositing a first plurality of conductive traces on a second surface of the substrate, the second surface opposite the first surface;
depositing a first insulation layer at least partially covering the first plurality of conductive traces;
depositing a second plurality of conductive traces on the first insulation layer; and
depositing a second insulation layer at least partially covering the second plurality of conductive traces; and
laminating the second insulation layer of the touch sensor to a cover material using an adhesive layer.

17. The method of claim 16 further comprising:
etching a hole through the substrate; and
forming a via in the hole, the via being coupled to the conductive layer and at least one conductive trace of the first plurality of conductive traces.

18. The method of claim 16 further comprising:
forming a via through the first insulation layer, the via being coupled to at least one conductive trace of the second plurality of conductive traces.

19. The method of claim 16, wherein the first plurality of conductive traces and the second plurality of conductive traces comprise a conductive silver ink.

20. The method of claim 19, wherein depositing the first plurality of conductive traces comprises printing the first plurality of conductive traces on the second surface of the substrate, and wherein depositing the second plurality of conductive traces comprises printing the second plurality of conductive traces on the first insulation layer.
